(19) United States
(12) Patent Application Publication
(10) Pub. No.: US 2011/0170330 A1
(43) Pub. Date: Jul. 14, 2011

(54) Graphene Memory Cell and Fabrication Methods Thereof

(75) Inventors: Barbaros Oezyilmaz, Singapore (SG); Yi Zheng, Singapore (SG); Guang Xin Ni, Singapore (SG); Chee Tat Toh, Singapore (SG)

(73) Assignee: NATIONAL UNIVERSITY OF SINGAPORE, Singapore (SG)

(21) Appl. No.: 13/120,108

(22) PCT Filed: Sep. 23, 2009
(86) PCT No.: PCT/SG2009/000352

§ 371 Date: Mar. 21, 2011

Related U.S. Application Data
(60) Provisional application No. 61/192,967, filed on Sep. 23, 2008.
(60) Provisional application No. 61/269,629, filed on Jun. 26, 2009.

(51) Int. Cl. G11C 11/22; H01L 27/115; H01L 21/8246

(52) U.S. Cl. 365/145; 257/9; 438/3; 257/E27.102; 257/E21.663

(57) ABSTRACT

The disclosed memory cell (10) comprises a graphene layer (16) having controllable resistance states representing data values of the memory cell (10) In one exemplary embodiment a non-volatile memory is provided by having a ferroelectric layer (18) control the resistance states. In the exemplary embodiment, binary ‘0’s and ‘1’s are respectively represented by low and high resistance states of the graphene layer (16), and these states are switched in a non-volatile manner by the polarization directions of the ferroelectric layer (18).

### FIELD OF THE INVENTION

The present invention relates generally to a memory cell and methods of fabricating a memory cell. In particular, but not exclusively, the present invention relates to a graphene-based memory cell and methods of fabrication thereof.

### BACKGROUND OF THE INVENTION

Memories and in particular non-volatile memories are in great demand for high-performance digital cameras, mp3 players, flash drives and cards, mobile phones, personal digital assistants (PDAs) and ultra-portable notebook personal computers (PCs) where high-density, ultra-compact, and low power-consumption storage devices are needed to replace the use of bulky hard disk drives.

An example non-volatile memory is NAND flash memory. In essence, each memory cell of a NAND flash memory comprises a silicon metal-oxide-semiconductor field-effect transistor (Si MOSFET) with an extra gate (called a floating gate) in addition to a control gate. The floating gate is surrounded by an insulating layer, which serves to trap any charge that is inserted into the floating gate by hot electron tunneling. The presence or absence of charge in the floating gate affects the current flow through the MOSFET channel, and this is sensed to determine whether the memory cell holds a ‘1’ or ‘0’ data value.

NAND flash memory has grown into a billion dollar industry in recent years because of its faster speed and more compact structure than hard disk drives, simple circuit design, and fast-increasing capacity due to its aggressive scalability. The main disadvantage of NAND flash is its slow random access time, which is 25 μs for the first byte. NAND flash also has limited write-erase-cycles, which is 100,000 cycles for block 0 and no guarantees for other blocks. Another disadvantage related to NAND flash is the necessity of ‘block erasure’, which means that although each bit of NAND flash can be changed from 1 to 0, a whole block (2112 bytes) must be erased to 1 if one bit of the specific block needs to be converted from 0 to 1. NAND flash also needs high voltages (20V) for writing and erasing processes.

Another non-volatile memory is ferroelectric RAM (FeRAM), which utilizes ferroelectric capacitors for data storage. In FeRAM, ‘1’ and ‘0’ data values are represented by two opposite polarization states, which can be retained without electrical power. Unlike NAND flash, FeRAM only needs a marginally higher writing voltage than the reading voltage. Moreover, both read and write can be done in a bit-by-bit fashion in FeRAM. These two features allow FeRAM to have less power consumption than NAND flash, with a more balanced read and write operation. The speed of FeRAM is comparable with dynamic random access memory (DRAM) but much faster than NAND flash. Reading of a FeRAM cell is carried out by forcing the cell into a particular state (e.g. a ‘0’ state). If the cell already held a ‘0’, no change will be observed at the output lines. If the cell held a ‘1’, the forcing into the opposite state causes a brief pulse of current at the output lines. The data value of the cell is thus determined from the presence or absence of this pulse. The main disadvantage of FeRAM, however, is that the reading process of the ‘1’ state is destructive, and a following re-writing process is required to get the state back to ‘1’. Also, the scalability of FeRAM is still unclear.

### SUMMARY OF THE INVENTION

In general terms, the present invention relates to a memory cell comprising graphene as the working medium. A volatile operation may be provided by switching the graphene using known gate dielectrics, while a non-volatile operation may be provided by switching the graphene using a ferroelectric layer as the gate dielectric.

In one specific expression, the present invention relates to a memory cell comprising a graphene layer having controllable resistance states representing data values of the memory cell.

Preferably the memory cell further comprises a ferroelectric layer configured to control the resistance states.

Preferably the graphene layer is configured to be in a high resistance state when the ferroelectric layer is depolarized to have zero remnant polarization, and is configured to be in a low resistance state when the ferroelectric layer is polarized to have non-zero remnant polarization. In another form, the memory cell further comprises a top electrode electrically coupled to the ferroelectric layer, wherein the graphene layer is configured to be in a high resistance state when an asymmetrical voltage sweep is applied to the top electrode for ferroelectric depolarization, and wherein the graphene layer is configured to be in a low resistance state when a symmetrical voltage sweep is applied to the top electrode for polarizing the ferroelectric layer.

Preferably the high resistance state and the low resistance state have a resistance change ratio greater than 500%. This is advantageous as it allows a clear delineation of the data values (e.g. 0 and 1) being represented by the resistance states, although resistance change ratio of 50% would be sufficient for this purpose.

Preferably, in a first form, the graphene layer is arranged between the ferroelectric layer and a dielectric layer on a conducting substrate. In this form, the method preferably further includes forming a top electrode on the ferroelectric layer. In a second form, the ferroelectric layer is arranged between the graphene layer and a dielectric layer on a conducting substrate. In the second form, there is preferably a bottom electrode on the dielectric (using the substrate). In a third form, the epitaxial ferroelectric layer is arranged between the graphene layer and a conducting oxide substrate. In the first and third forms, the conducting substrate and the conducting oxide substrate serve as bottom electrodes.

Preferably the graphene layer includes a background doping level greater than zero. This allows a symmetrical writing process to be advantageously implemented. In one form, this allows the graphene layer to be in a high resistance state when a positive voltage pulse is applied to a top electrode of the memory cell, and in a low resistance state when a negative voltage pulse is applied to the top electrode. The background doping level may be achieved by providing the graphene layer as epitaxial graphene on a SiC substrate in one form. In another form, the graphene layer is doped with donor or acceptor molecules and is arranged on one surface of the ferroelectric layer, and with an electrode being formed on an opposite surface of the ferroelectric layer.

The background doping level is preferably controllable to adjust a resistance change ratio of the resistance states. This advantageously allows multiple resistance change ratios to be used to represent multiple bits of data.

Preferably, in a first form, the graphene layer is chemically derived from graphene oxide. In a second form, the graphene layer is chemically modified graphene, such as graphane. In a third form, the graphene layer is grown by chemical vapor deposition (CVD), low pressure CVD, or plasma-enhanced CVD on copper, nickel, cobalt or any other surface, which allows for large-scale graphene. In a fourth form, the graphene layer is mechanically exfoliated from bulk graphite. In terms of thickness, the graphene layer may be one layer, two layers, three layers or any other gate tunable thickness.

Preferably the graphene layer is a pristine two-dimensional sheet, or patterned into nanoscale dimensions of dots, dot arrays, nanowires or nanowire arrays. The graphene layer may have an intrinsic energy band structure or a band gap engineered by lateral confinement, strain stress or electric field.

Preferably the graphene layer is gated by top gates, side gates, back gates or a combination of one or more of top gates, back gates and side gates.

Preferably the memory cell is fabricated on a flexible and/or transparent substrate.

Preferably the arrangement of the graphene layer is one selected from: directly in contact with the ferroelectric layer, and separated from the ferroelectric layer by an ultrathin insulating layer.

Preferably the memory cell further comprises an alternating stack of graphene layer and ferroelectric layer, each layer being contacted (or contactable) separately. This is advantageous as it allows a three-dimensional memory architecture to be realized.

In another specific expression, the present invention relates to a method of fabricating a memory cell comprising providing a graphene layer having controllable resistance states to represent data values of the memory cell.

Preferably the method further comprises providing a ferroelectric layer configured to control the resistance states.

Preferably, in a first form, the providing step comprises arranging the graphene layer on a dielectric layer on a conducting substrate, and forming a ferroelectric thin film over the graphene layer. In this form, the method preferably further includes forming a top electrode on the ferroelectric thin film. In a second form, the providing step comprises forming a ferroelectric thin film on a dielectric on a conducting substrate, and arranging the graphene layer over the ferroelectric thin film. In this form, the method preferably further comprises forming a bottom electrode between the ferroelectric thin film and the dielectric layer. In a third form, the providing step comprises forming an epitaxial ferroelectric thin film on a conducting oxide, and arranging the graphene layer over the ferroelectric thin film. In this form, the conducting oxide functions as a bottom electrode.

Preferably, where background doping is desired, the providing step comprises depositing the graphene layer on a ferroelectric substrate, and doping the graphene layer with donor or acceptor molecules. Alternatively or additionally, this may be achieved by growing epitaxial graphene on a SiC substrate. Ferroelectric background gating may also be used.

Preferably, in a first form, the providing step comprises chemically deriving the graphene layer from graphene oxide. In a second form, the providing step comprises chemically modifying graphane to provide the graphene layer. In a third form, the providing step comprises growing the graphene layer by chemical vapor deposition (CVD), low pressure CVD, or plasma-enhanced CVD on copper, nickel, cobalt or any other surface, which allows for large-scale graphene. In a fourth form, the providing step comprises mechanically exfoliating from bulk graphite. In terms of thickness, the graphene layer may be one layer, two layers, three layers or any other gate tunable thickness.

Preferably the providing step comprises providing the graphene layer as one layer, two layers, three layers or any other gate tunable thickness.

Preferably the providing step comprises providing the graphene layer as a pristine two-dimensional sheet, or patterning into nanoscale dimensions of dots, dot arrays, nanowires or nanowire arrays.

Preferably the providing step comprises providing the layers on a flexible and/or transparent substrate.

Preferably the providing step comprises providing the graphene layer directly in contact with the ferroelectric layer, or separating the graphene layer from the ferroelectric layer by an ultrathin insulating layer. Preferably the method further comprises forming an alternating stack of graphene layer and ferroelectric layer.

As will be apparent from the following description, embodiments of the present invention provide a memory cell that benefits from a low bias writing and reading process, which accordingly reduces power consumption of devices using the memory cell. Furthermore, data readings from the memory cell of the present invention are not destructive, which avoids re-writing processes and thus increases switching time and reduces power usage. These factors when combined with various factors that will be later described result in a memory device that is capable of high performance, fast access times, high reliability, low power consumption and non-volatility. The present invention also provides a non-volatile memory solution for cost-effective flexible electronics by using flexible and/or transparent substrates and polymer ferroelectric. These and other related advantages will be readily apparent to skilled persons from the description below.

### BRIEF DESCRIPTION OF THE FIGURES

Non-limiting preferred embodiments of the memory cell will now be described with reference to the accompanying figures in which:

FIGS. 1A and 1B are a cross-section schematic and a perspective cutaway schematic respectively of one embodiment of the memory cell,

FIG. 2 is a graph showing the field-dependent resistance of a graphene layer,

FIGS. 3A and 3B are resistance versus electric field graphs showing the resistance of the graphene layer at the zero polarization (i.e. bit ‘1’) and at the non-zero polarization (i.e. bit ‘0’),

FIGS. 3C and 3D are two series of polarization versus electric field (P-E) hysteresis loops showing the writing of a ‘1’ state into the memory cell from different initial states,

FIGS. 3E and 3F are two series of polarization versus electric field (P-E) hysteresis loops showing the writing of a ‘0’ state into the memory cell from different initial states,

FIGS. 4A and 4B are cross-section schematics of alternative embodiments of the memory cell,

FIG. 4C is a perspective cutaway schematic of a flexible memory cell using a flexible and/or transparent substrate and polymer ferroelectric,

FIG. 5 is a graph showing the hysteresis loop of graphene resistance versus gate voltage for a graphene-ferroelectric memory cell with a gate voltage sweep between −85V and 85V,

FIGS. 6A to 6D are graphs showing the hysteresis loops of graphene resistance versus gate voltage for effecting various data value changes, i.e. bit writing in the memory cell,

FIGS. 7A and 7B are cross-section schematics, hysteresis loops and graphs of a non-electrostatic biased memory cell and an electrostatic biased memory cell respectively,

FIGS. 8A to 8C are cross-section schematics and hysteresis loops showing the change in the hysteresis loop following electrostatic bias, and the operation of writing a ‘1’ and a ‘0’ into the memory cell,

FIGS. 9A and 9B are cross-section schematics of two embodiments of the memory cell with electrostatic bias, and

FIG. 10 is a graph of resistance change ratio versus background doping levels for multi-bit-per-cell data storage.

### DETAILED DESCRIPTION OF PREFERRED EMBODIMENTS

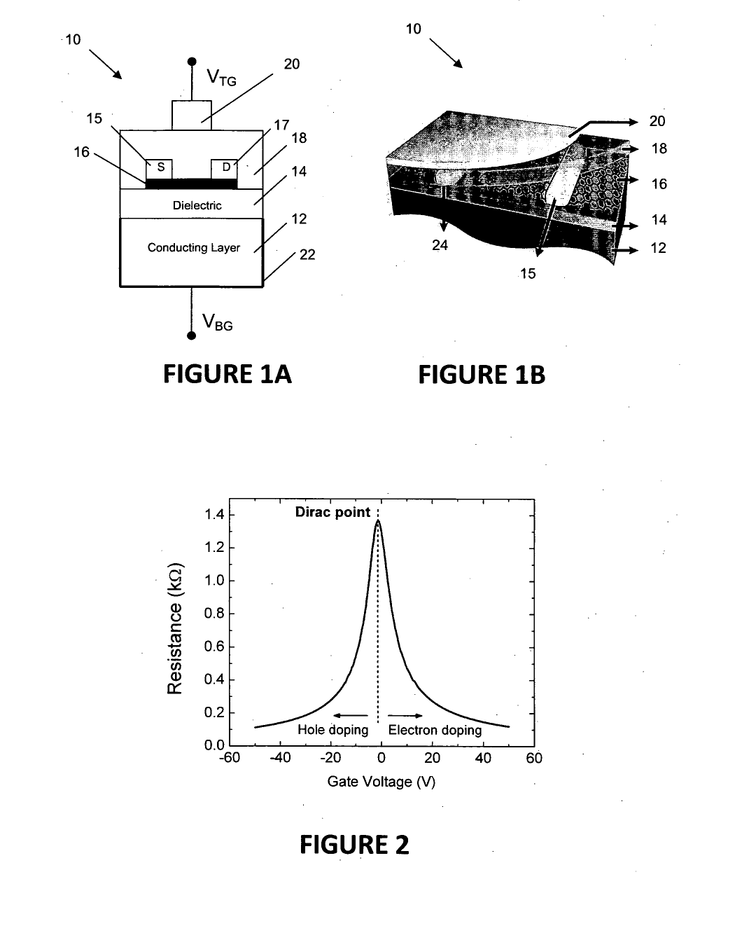

Referring to FIGS. 1A and 1B, one preferred embodiment of the memory cell 10 is shown. The memory cell 10 includes a conducting substrate 12 and a dielectric layer 14 on the conducting substrate 12. A graphene layer 16 comprising a graphene sheet is arranged over the dielectric layer 14 and is encapsulated by a ferroelectric layer 18 comprising a thin film of ferroelectric. The graphene layer 16 is electrically coupled to a source region 15 and a drain region 17 of the memory cell 10. A top electrode 20 that is electrically coupled to the ferroelectric layer 18 and a bottom electrode 22 (the conducting substrate) that is electrically coupled to the dielectric layer form two alternative gate regions of the memory cell 10. Contacts 24 are also provided on the graphene layer 16 for connection to and from the memory cell 10. The arrangement of the above layers results in a non-volatile memory cell having a sandwich structure of metal/ferroelectric/graphene, best depicted in FIG. 1B.

The graphene layer 16 comprises graphene, which is a layer of carbon atoms with a two-dimensional hexagonal crystal structure. It has been found that one of the unique properties of graphene is its field-dependent conductivity. Referring to the graph FIG. 2, this field-dependent conductivity is shown as an inverted V-shape graph of differential resistance versus gating voltage. Depending on the electric field established by the gating voltage, charge carriers in graphene can be tuned continuously from holes to electrons crossing the minimum conduction point (i.e. the peak of the V-shape, also known as the Dirac point). As a result, when single graphene sheets are placed on a dielectric layer on a conducting substrate (e.g. silicon wafer) to form a graphene-dielectric-gate structure, bias applied to the conducting substrate with the graphene sheets grounded resulted in a change in the charge carrier concentration as well as conductivity.

The application of graphene in the present invention utilizes the field-dependent conductivity of graphene by representing data values using different resistance states of the graphene layer (cf. magnetic data storage). The different resistance states of graphene, however, cannot be retained as long as the external field is switched off. To overcome this volatile nature of the field-dependent electrical resistance, one preferred embodiment of the present invention utilizes the remnant field of a ferroelectric layer to set a particular resistance state of the graphene layer.

As will be explained below, in one preferred embodiment, binary ‘0’s and ‘1’s are represented by the different resistance states of the graphene layer, and these states are switched in a non-volatile manner by the polarization magnitudes of the ferroelectric layer.

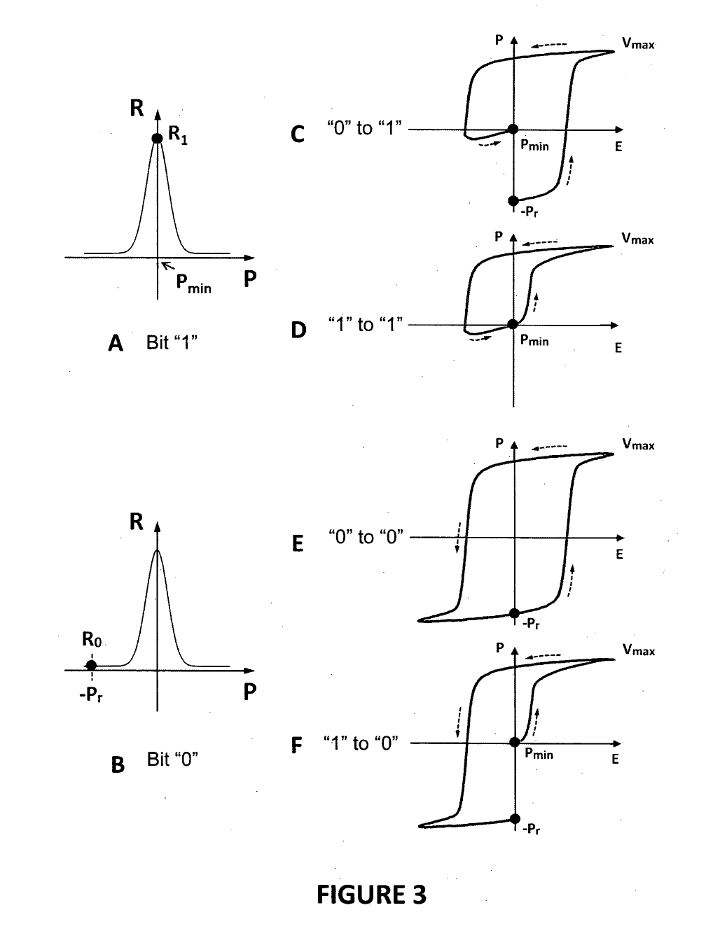

The preferred operation of the above arrangement is shown in FIGS. 3A to 3F. Referring to the resistance versus polarization graphs of FIGS. 3A and 3B (which again show the field-dependent resistance of the graphene layer), the setting of the ferroelectric layer at a zero remnant polarization Pₘᵢₙ and a non-zero remnant polarization −Pᵣ result in two specific resistance state of the graphene layer. In the embodiment shown, the binary information is a high resistance state (having resistance R₁) representing the data value ‘1’ and a low resistance state (having resistance R₀) representing the data value ‘0’ respectively. When reading of the stored binary value is required, all that is necessary is to detect the resistance of the graphene layer. It will be appreciated that reading the data value is not destructive since the memory value is retained by the ferroelectric layer, which maintains the remnant polarization until such time as it is depolarized or polarized differently.

FIGS. 3C and 3D show the operation to write a binary value ‘1’ into the preferred form memory cell. Referring to the graphs of FIGS. 3C and 3D, two different polarization versus electric field (P-E) hysteresis loops of the ferroelectric layer are shown. In FIG. 3C, the ferroelectric layer is initially polarized with a remnant polarization of −Pᵣ, while in the FIG. 3D, the ferroelectric layer is initially polarized with a zero polarization. In both cases, the ferroelectric layer is subjected to a minor hysteresis loop with an asymmetrical V_{TG} sweep from 0 to Vₘₐₓ, Vₘₐₓ to V_{Ec}, and from V_{EC} back to 0. The minor hysteresis loops minimize the polarization in the ferroelectric layer and set the memory cell into bit ‘1’, independent on the initial states. It will be appreciated that the remnant polarization is the result of electrical dipoles within the ferroelectric layer being aligned in one direction in response to the applied electric field, and Ec is the coercive field of the ferroelectric.

Referring now to FIGS. 3E and 3F, the operation to write a binary value ‘0’ into the preferred form memory cell is shown. As before, FIGS. 3E and 3F show two different polarization versus electric field (P-E) hysteresis loops of the ferroelectric layer. In FIG. 3E, the ferroelectric layer is initially polarized with a remnant polarization of −Pᵣ, while in the FIG. 3F, the ferroelectric layer is initially polarized with a zero polarization. To write bit ‘0’, the ferroelectric layer is subjected to a major hysteresis loop with a symmetrical V_{TG} sweep from 0 to Vₘₐₓ, Vₘₐₓ to −Vₘₐₓ, and from −Vₘₐₓ back to 0. The major hysteresis loops maximize the remnant polarization in the ferroelectric layer and set the memory cell into bit ‘0’, also independent on the initial states. It has been found that a resistance change of at least an order of magnitude between the high resistance state and the low resistance state can be reproducibly achieved. As before, when reading of the stored value is required, all that is necessary is to detect the resistance of the graphene layer.

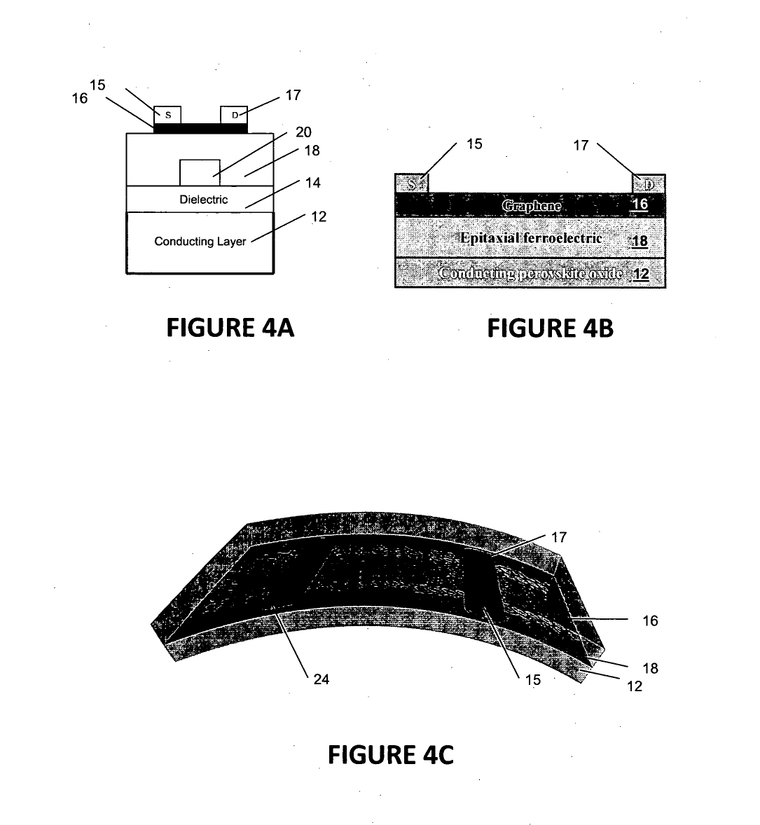

Alternative preferred embodiments of the memory cell are illustrated in FIGS. 4A and 4B. In FIG. 4A, the ferroelectric layer 18 is provided on the dielectric layer 14 while in FIG. 4B the ferroelectric layer 18 is provided on a conducting oxide layer 14, and the graphene layer 16 is provided over the epitaxial ferroelectric layer 18. The top electrode 20 in these arrangements underlies the ferroelectric layer 18 (i.e. between the ferroelectric layer 18 and the dielectric layer 14 in FIG. 4A, and the conducting perovskite oxide layer 14 in FIG. 4B). The arrangements of these embodiments allow thermal processing of the ferroelectric layer 18.

The fabrication of the memory cell in a volatile embodiment comprises providing a graphene layer having different resistance states representing data values. The fabrication of the memory cell in a non-volatile embodiment comprises providing a graphene layer and a ferroelectric layer typically on a substrate (although one embodiment uses the ferroelectric layer as the substrate), with the ferroelectric layer being configured to controllably set the resistance state of the graphene layer. In one preferred embodiment, the memory cell is fabricated on a flexible and/or transparent substrate 12, as shown in FIG. 40. For the embodiment of FIG. 1A, the method includes forming a bottom electrode using the conducting substrate 12, providing a graphene layer 16 on the conducting substrate 12, and providing a ferroelectric layer 18 on the graphene layer 16. In one example, the method comprises forming bottom electrodes by thermal evaporation of metal, and patterning the bottom electrode by electron-beam lithography. One or more additional top gates, side gates, back gates or a combination thereof may also be similarly fabricated. The method in the preferred form also includes spin-coating a thin film of poly(vinylidenefluoride-trifluoroethylene) P(VDF-TrFE) on the graphene layer or on the dielectric layer to form the ferroelectric layer. The arrangement of the graphene layer on the ferroelectric layer is one selected from: directly in contact with the ferroelectric layer, and separated by an ultrathin insulating layer.

The graphene layer is fabricated in one or more of the following ways: chemically derived from graphene oxide, fabricated from chemically modified graphene (e.g. graphane), and grown by one or more of chemical vapor deposition (CVD), low pressure CVD, or plasma-enhanced CVD on copper, nickel, cobalt or any other surface, which allows for large-scale graphene. The graphene layer may also be mechanically exfoliated from bulk graphite. The thickness of the graphene layer is selected from the group consisting of: one layer, two layers, three layers and any other gate tunable thickness.

The graphene layer may be a pristine two-dimensional sheet, or patterned into nanoscale dimensions of dots, dot arrays, nanowires or nanowire arrays. In terms of band gap, the graphene layer has an intrinsic energy band structure or has a band gap engineered by lateral confinement, strain stress or electric field.

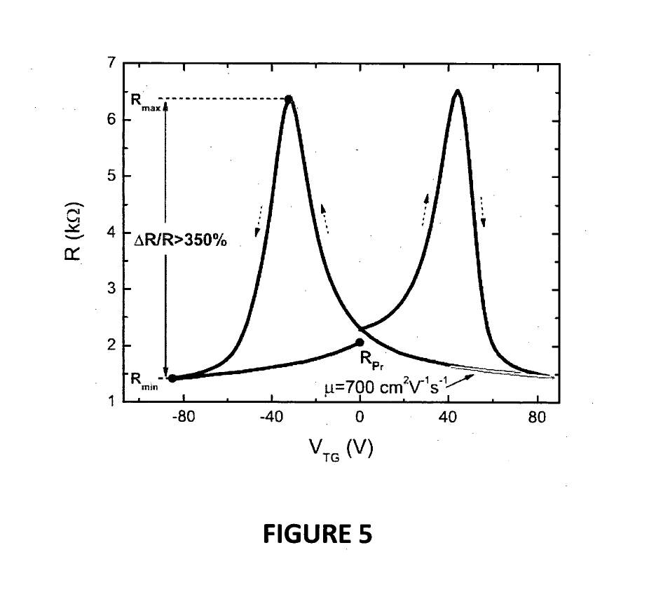

The electric hysteresis loop for the graphene resistance R as a function of top gate (i.e. top electrode) voltage V_{TG} for one sample of the memory cell of FIG. 1 is shown in FIG. 5. It is notable that there are pronounced hysteresis in resistance measurements when the top gate voltage is swept in a closed loop. A hysteretic switching is shown between the maximum resistance Rₘₐₓ and the minimum resistance Rₘᵢₙ. For the sample tested, the resistance change ratio, ΔR/R=(Rₘₐₓ−Rₘᵢₙ)/Rₘᵢₙ was larger than 350%.

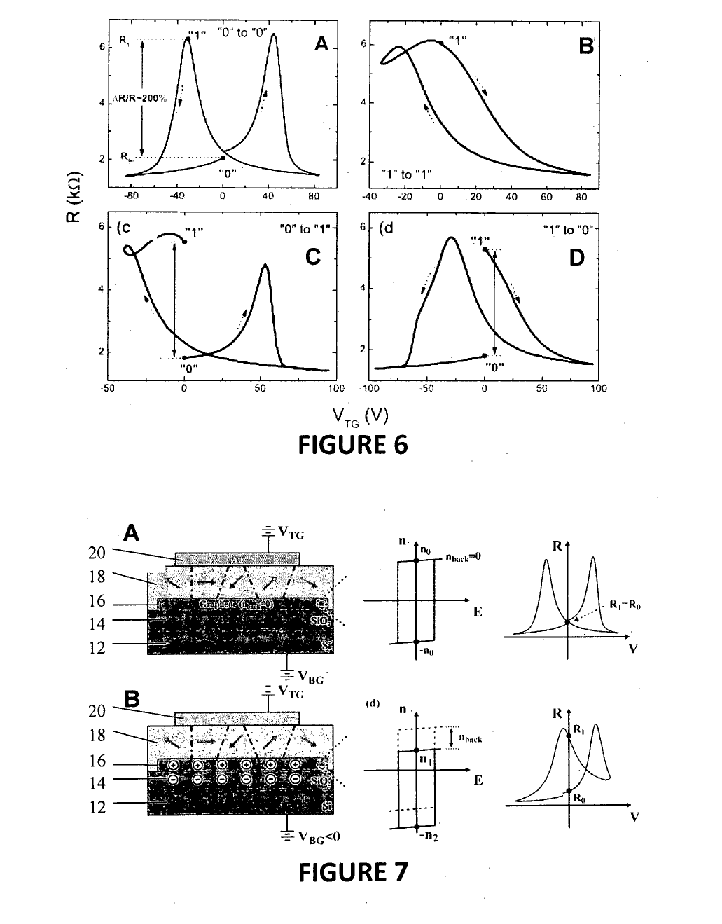

In the preferred embodiment, the maximum resistance peak Rₘₐₓ represents the data value ‘1’ while the data value ‘0’ is represented by R_{Pr}. As shown in FIGS. 6A and 6D, a major hysteresis loop, corresponding to a full symmetrical V_{TG} sweep sets the memory to ‘0’, independent of the existing state. In FIG. 6A, ‘0’ has been rewritten into ‘0’, while in FIG. 6D, the data value has been reset from ‘1’- to ‘0’. In contrast, writing ‘1’ into the memory cell requires a minor hysteresis loop with an asymmetrical V_{TG} sweep to minimize the polarization in the ferroelectric layer when V_{TG} is back to zero. As shown in FIGS. 6B and 6C, a minor hysteresis loop sets the resistance state of the graphene channel to near Rₘₐₓ independent of the initial state of ‘1’ or ‘0’. Thus, using major and minor hysteresis loops, it is possible to realize nonvolatile switching or setting of values in the memory cell of the present invention. As outlined earlier, the read out of the information set in the memory cell can be simply done by measuring the cell resistance using an excitation current as low as 1 nA.

The above embodiments clearly show that reversible nonvolatile switching between a high resistance state and a low resistance state in a graphene layer can been realized by implementing major or minor hysteresis loops. The resistance hysteresis loop and the switching between the high and low resistance states are due to the electric-dipole-induced doping in graphene by the ferroelectric thin film (i.e. hysteretic ferroelectric doping). In the samples prepared to date, the resistance change ΔR/R exceeds 500% (i.e. the resistance at the high resistance state is more than 6 times that of the low resistance state) and may be further improved by improving the quality of ferroelectric/graphene interface, the charge carrier mobility in graphene, and by increasing the remnant polarization of ferroelectric thin film. One approach to increase the remnant polarization of the ferroelectric layer is by applying a larger electric field. An alternative approach would be to prepare graphene sheets directly on ferroelectric substrates, which would allow the use of other ferroelectric materials with much higher remnant polarization. Another approach would be to open a band gap in the graphene layer, either by using bilayer graphene or graphene nanoribbons.

Although the above embodiments are workable using an asymmetrical writing strategy (i.e. using different hysteresis loops), the requirement of an asymmetrical writing strategy may complicate the device operations and circuit designs for memory and data storage applications. To address this, a further preferred embodiment of the invention implements an electrostatic bias technique. Specifically, in this alternative embodiment, the hysteretic ferroelectric doping in the graphene layer is modified unidirectionally by introducing a background doping level (herein n_{back}) in the graphene layer before the ferroelectric polarization, The n_{back} exerts electrostatic forces/bias on the electric dipole flipping and produces asymmetrical remnant polarizations Pr′ and Pr″ in the ferroelectric layer.

The effect of the electrostatic bias technique is shown relative to a non-electrostatic-bias technique in FIGS. 7A and 7B. In both figures, the ferroelectric layer is illustrated with arrows showing directions of its electrical dipoles. FIG. 7A shows the effect without electrostatic bias. The ferroelectric gating introduces two symmetrical zero-field doping levels in graphene with opposite signs. With symmetrical voltage sweeping, no resistance change is observed due to the ambipolar field dependent conductance in graphene. FIG. 7B shows the effect with electrostatic bias. As described earlier, electrostatic bias as a result of background doping n_{back} in graphene (electrostatic bias can also be provided by a ferroelectric gate) modifies the hysteretic ferroelectric doping unidirectionally, allowing two distinct resistance states to be realized with symmetrical voltage sweeping. The resistance change ratio (ΔR/R) in this embodiment can be determined using equation (1) below.

$$\frac{Δ R}{R} = \frac{{R}_{1} - {R}_{0}}{{R}_{0}} = \frac{2 {n}_{back}}{{n}_{0} - {n}_{back}} \qquad ( 1 )$$

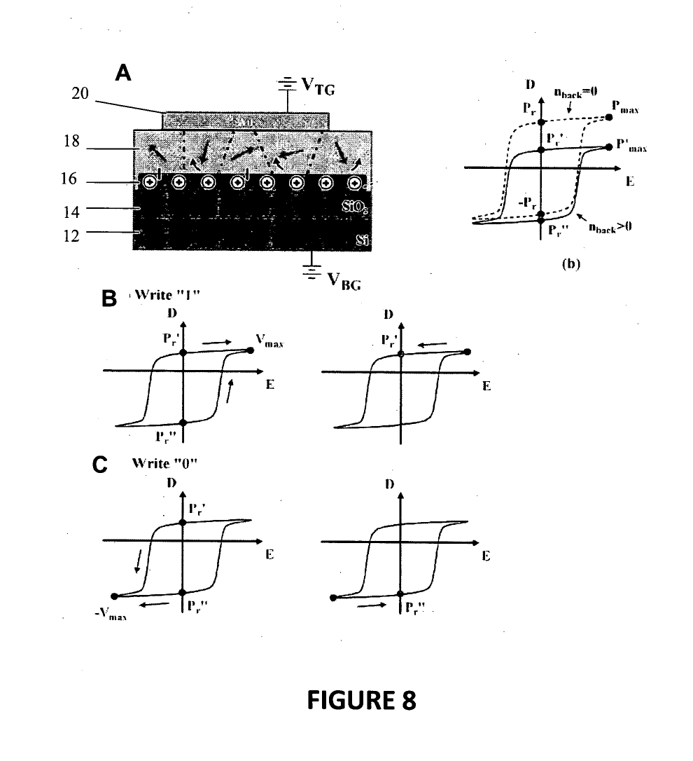

Using the electrostatic bias effect, symmetrical bit writing in the memory cell can be realized by symmetrical voltage pulses, which simplifies the writing procedures by applying voltage pulses to flip the electric dipole orientations in the ferroelectric layer. This is shown in FIGS. 8A to 8C. FIG. 8A shows a cross-section schematic of the memory cell with the graphene layer having n_{back} greater than zero, and the resulting effect of the n_{back} of producing asymmetrical remnant polarizations Pr′ and Pr″ in the ferroelectric layer. With reference to FIGS. 8B and 8C, the memory cell in this embodiment is able to switch the memory states from ‘0’ to ‘1’ when a positive voltage pulse is applied to the top electrode. After the positive pulse, the polarization in the ferroelectric will remain at Pr′, setting the graphene layer into the high resistance value, R₁ (as shown in FIG. 7B). Conversely, to switch from ‘1’ to ‘0’, a negative voltage pulse is applied to the top electrode. After the negative pulse, the polarization in the ferroelectric will remain at Pr″, setting the graphene layer into the low resistance value, R₀ (as shown in FIG. 7B). In contrast, without electrostatic bias and where the field dependent conductance of the graphene is not bipolar, symmetrical writing would lead to the same resistance state due to symmetrical remnant polarizations of Pᵣ and −Pᵣ (as shown in FIG. 7A).

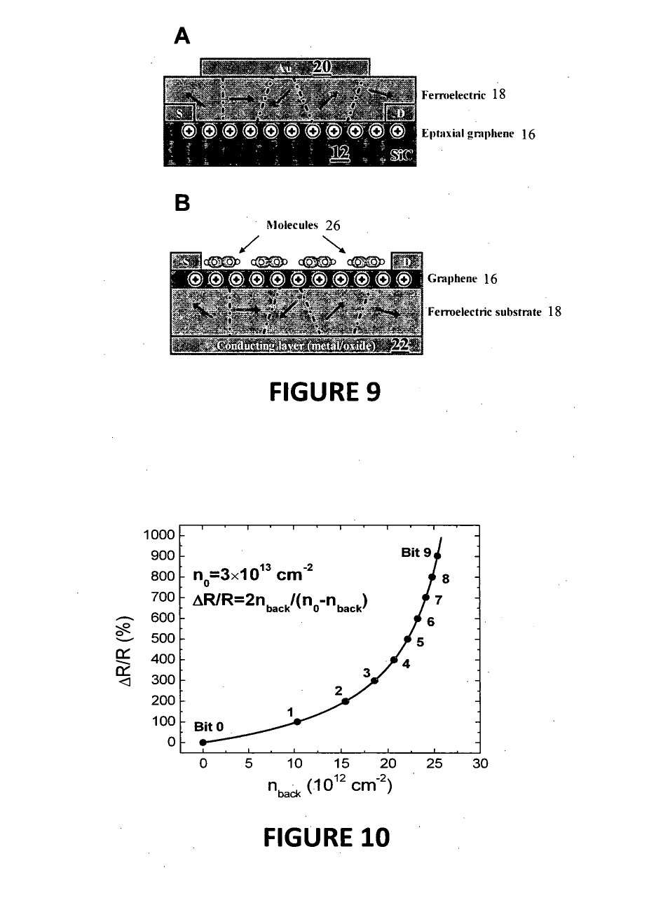

Two embodiments of the memory cell utilizing electrostatic bias are shown in FIGS. 9A and 9B. In FIG. 9A, the memory cell has a similar structure to that of FIG. 1A but is formed by growing epitaxial graphene 16 on a silicon carbide (SiC) substrate 12. In this embodiment, the graphene layer 16 is doped (heavily in the preferred embodiment, represented by the positive ions in the layer 16) by the substrate 12 in a controlled manner by controlling the surface reconstruction of SiC. In FIG. 9B, the graphene layer 16 is formed by chemical vapor deposition (CVD) or mechanical exfoliation on the ferroelectric layer 18, with the ferroelectric layer 18 acting as the substrate. In this embodiment, the graphene layer 16 is doped (heavily in the preferred embodiment) by donor/acceptor molecules 26, such as pentacene, rubrene or tetracyanoquinodimethane (TCNQ), and is arranged on one surface of the ferroelectric layer 18, with the bottom electrode 22 being formed on an opposite surface of the ferroelectric layer 18.

In another alternative embodiment of the present invention, the background doping level or n_{back} in graphene is controlled such that the resistance change ratio (ΔR/R) in memory cell is tuned continuously. The n_{back} can be controlled by applying a back gate voltage (V_{BG}) to the substrate. For non-volatile applications, tunable n_{back} can be provided using a ferroelectric back gate. Such a gate-tunable ΔR/R is advantageous as it allows multi-bit-per-cell data storage. The effect of a gate-tunable ΔR/R can be seen from FIG. 10, which shows the relationship between n_{back} and the resulting resistance change ratio ΔR/R. Here, n₀ (Pᵣ/e) represents the zero-field ferroelectric doping in graphene when n_{back}=0. Specifically, by changing n_{back} gradually, ΔR/R is tuned continuously from zero to over 1000% (although high mobility samples have shown a much larger range, e.g. to over 10000%). The different ΔR/R values are then used to represent multi-bit information storage. This is possible as an adjustment of n_{back} produces different hysteresis loops with different values for R₁ and R₀. As each set of R₁ and R₀ allows a 1-bit storage by one specific ΔR/R, multiple sets of R₁ and R₀ results in the ability to store multiple bits. For example, if three sets of R₁ and R₀ are detectable, a 3-bit storage (i.e. 00, 01, and 10) may be implemented. In the example of FIG. 10, a 10-bit-per-cell tuning is shown, in which every 100% change in ΔR/R is defined as a bit. Compared to binary information, a 10-bit-per-cell storage increases data storage capacities by 5 times with the same unit cell size. This can be enhanced and utilized even more so using very high mobility devices where the resistance change ratio is 10000 or more. Furthermore, if band gap opening (e.g. lateral confinement, ribbons, dots and antidote arrays) is used, desirable changes may be made in the graphene band structure (e.g. hydrogenation, electric field induced gap, e.g. bilayer).

The benefits arising from the present invention will be clear from the foregoing description. For instance, by utilizing the field-dependent electrical resistance of a graphene layer, the memory cell is fast enough to match the current DRAM. Where the graphene layer is controlled by a ferroelectric layer, the resulting memory is also non-volatile. Both the writing and reading process in the memory cell of the present invention is realized by low working bias, which accordingly reduces power consumption of devices using the memory cell. In the case of graphene-P(VDF-TrFE) memory, for reading, a few tens of μV are required to read the resistance value of the graphene working channel; while for writing, less than 10 V working bias is achievable by limiting the P(VDF-TrFE) thickness below 100 nm. It will be appreciated that an organic ferroelectric layer allows also for simple integration with flexible transparent electronics and acts simultaneously also as a capping and passivation layer. Furthermore, data readings from the memory cell of the present invention are not destructive and thus no following re-writing is required. This increases the switching cycles and reduces power usage. Due to the stable, chemically inert properties of graphene, the memory cell of the present invention provides a reliable data storage means even when compared to conventional data storage. Graphene, which has an ultra-high charge carrier mobility, also gives the memory cell extremely fast reading speed, typically several tens of femtoseconds. Even if these speeds are not utilized due to design constrains of an actual working device, the fact that these devices have very high mobilities translate to large power savings when they are operated at orders of magnitude slower speeds. These factors when combined with the sensitive field-dependent electrical resistance of the graphene layer and the fast switching time of the ferroelectric layer (several tens of nanoseconds) provide a memory device that has high performance, fast access times, high reliability, low power consumption and non-volatility. For the graphene-ferroelectric memory cell, P(VDF-TrFE) is preferable for integration with flexible electronics with cost-effective solution for non-volatile data storage, while inorganic ferroelectric, such as lead zirconate titanate (PZT) based materials, is preferred when high performance, ultra-fast reading & writing graphene-ferroelectric memory is needed (in the case of PZT-based material, the switching speed can be as fast as 280 ps). In other words, the ferroelectric gate may be made out of inorganic or organic materials.

To summarize the above:

1. Graphene memory relies on the electronic intrinsic properties of the material. The carrier concentration can be tuned by means of an electric field effect. At large carrier concentrations (high doping) the device resistance is low. At low carrier concentration (small doping) the device resistance small. Independent of the doping, the carrier mobilities of graphene are large. The two resistance states can be used to store information, such that a large resistance state is ‘donated’ to one bit of information and a small resistance to the complimentary bit of information.
2. The device state can be switched from one state to another by changing the carrier concentration by electric field effect, provided by electric gates.
3. The electric field effect can be either realized with volatile gates or non-volatiles gates.
4. In the presence of volatile gates, the memory will be volatile memory. In the case of non-volatile gates, the memory will be non-volatile memory.
5. The non-volatile gate can be realized by ferroelectric materials.
6. The device operation can be such that only one gate acts on an otherwise undoped (neutral) graphene. This leads to an asymmetric writing scheme.
7. The device operation can be such that one uses a ferroelectric gate to an already charged graphene sheet. This charging can be achieved by a number of ways (substrate induced, e.g. SiC, backgate induced (either volatile or non-volatile), chemical doping induced, or any combination of these). This has been herein referred to as ‘electrostatic bias’ and leads to a simple read write scheme (symmetric writing).
8. In the case of electrostatic bias, it is possible to achieve a gate tunable ΔR/R which can vary over many orders of magnitude (at least 1000%, in very high quality samples 100000% and in bandgap engineered samples >>10000%). It is also possible that the complementary gate for the electrostatic bias could be in principle volatile.

It is also possible to construct a multilayer graphene memory cell. The structure in this alternative embodiment would consist of an alternating stack of graphene and ferroelectric gate, each layer contacted separately and hence a 3D memory architecture is achieved, where each layer forms a unit cell. This may be implemented using graphene or graphene oxide, e.g. by spin-coating the graphene and ferroelectric gate layer by layer.

In a further alternative embodiment, organic ferroelectric materials are used which are transparent and flexible to provide a capping layer for flexible, transparent electronic devices based on graphene (if graphene is also used as a contact metal for the gates).

The foregoing describes non-limiting preferred embodiments, which, as will be understood by those skilled in the art, may be subject to variations or modifications in design, construction or operation without departing from the scope of the claims. For example, although preferred embodiments have been described with reference to non-volatile arrangements and operations, this is not essential as volatile operations not requiring a ferroelectric gate dielectric are also envisaged. Also, where a ferroelectric gate is used, it is not essential that zero remnant polarization and non-zero remnant polarization be used to define each of the binary values ‘1’ and ‘0’. Where necessary or desired, one remnant polarization may be defined such that the resulting resistance of the graphene sheet at that polarization represents one data value, and the absence of that polarization (resulting in other values of resistance) may represent another data value. Changing from non-zero remnant polarization to substantially zero polarization may be accomplished via known depolarization techniques. In addition, although the x-axis of the graphs of FIGS. 3A and 3B have been described as the polarization of the ferroelectric layer, skilled persons will appreciate that the x-axis may also represent the bottom gate voltage (V_{BG} in FIG. 1A) or the top gate voltage (V_{TG} in FIG. 1A). That is to say, the field-dependent resistance characteristic of the graphene layer may be expressed in terms of the voltage applied to the top or bottom gate of the memory cell in addition to the polarization of the ferroelectric layer. Where an insulating substrate is desirable, this may be flexible and/or transparent. If a backgate is desirable, the arrangement may be such that the graphene sits on the bottom gate structure comprising of a highly conducting layer separated from the graphene by an insulating layer. The above variations, for instance, are intended to be covered by the scope of the claims.

1. A memory cell comprising a graphene layer having controllable resistance states representing data values of the memory cell.

2. The memory cell of claim 1 further comprising a ferroelectric layer configured to control the resistance states.

3. The memory cell of claim 2 wherein the graphene layer is configured to be in a high resistance state when the ferroelectric layer has zero remnant polarization, and wherein the graphene layer is configured to be in a low resistance state when the ferroelectric layer has non-zero remnant polarization.

4. The memory cell of claim 2 further comprising a top electrode electrically coupled to the ferroelectric layer, wherein the graphene layer is configured to be in a high resistance state when an asymmetrical voltage sweep is applied to the top electrode, and wherein the graphene layer is configured to be in a low resistance state when a symmetrical voltage sweep is applied to the top electrode.

5. The memory cell of claim 3 wherein the high resistance state and the low resistance state have a resistance change ratio greater than 500%.

6. The memory cell of claim 2 wherein the graphene layer is arranged between the ferroelectric layer and a dielectric layer on a conducting substrate.

7. The memory cell of claim 2 wherein the ferroelectric layer is arranged between the graphene layer and a dielectric layer on a conducting substrate.

8. The memory cell of claim 6 further comprising a bottom electrode using the conducting substrate.

9. The memory cell of claim 2 wherein the graphene layer is arranged on an epitaxial ferroelectric layer on a conducting oxide substrate.

10. The memory cell of claim 2 wherein the graphene layer includes a background doping level greater than zero.

11. The memory cell of claim 10 wherein the graphene layer is configured to be in a high resistance state when a positive voltage pulse is applied to a top electrode of the memory cell, and wherein the graphene layer is configured to be in a low resistance state when a negative voltage pulse is applied to the top electrode.

12. The memory cell of claim 10 wherein the graphene layer is epitaxial graphene on a SiC substrate.

13. The memory cell of claim 10 wherein the graphene layer is doped with donor or acceptor molecules and is arranged on one surface of the ferroelectric layer, and with an electrode being formed on an opposite surface of the ferroelectric layer.

14. The memory cell of claim 10 wherein the background doping level is controllable to adjust a resistance change ratio of the resistance states.

15. The memory cell of claim 14 wherein multiple resistance change ratios represent multiple bits of data.

16. The memory cell of claim 1 wherein the graphene layer is chemically derived from graphene oxide.

17. The memory cell of claim 1 wherein the graphene layer is chemically modified graphene.

18. The memory cell of claim 1 wherein the graphene layer is grown by chemical vapor deposition (CVD), low pressure CVD, or plasma-enhanced CVD on copper, nickel, cobalt or any other surface, which allows for large-scale graphene.

19. The memory cell of claim 1 wherein the graphene layer is one layer, two layers, three layers or any other gate tunable thickness.

20. The memory cell of claim 1 wherein the graphene layer is a pristine two-dimensional sheet, or patterned into nanoscale dimensions of dots, dot arrays, nanowires or nanowire arrays.

21. The memory cell of claim 1 wherein the graphene layer has an intrinsic energy band structure or has a band gap engineered by lateral confinement, strain stress or electric field.

22. The memory cell of claim 1 wherein the graphene layer is gated by top gates, side gates, back gates or a combination of one or more of top gates, back gates and side gates.

23. The memory cell of claim 1 wherein the memory cell is fabricated on a flexible and/or transparent substrate.

24. The memory cell of claim 1 wherein the arrangement of the graphene layer is one selected from: directly in contact with the ferroelectric layer, and separated by an ultrathin insulating layer.

25. The memory cell of claim 1 further comprising an alternating stack of graphene layer and ferroelectric layer, each layer being contacted separately.

26. A method of fabricating a memory cell comprising providing a graphene layer having controllable resistance states to represent data values of the memory cell.

27. The method of claim 26 further comprising providing a ferroelectric layer for controlling the resistance states.

28. The method of claim 27 wherein the providing step comprises arranging the graphene layer on a dielectric layer on a conducting substrate, and forming a ferroelectric thin film over the graphene layer.

29. The method of claim 26 wherein the providing step comprises growing epitaxial graphene on a SiC substrate.

30. The method of claim 27 wherein the providing step comprises forming a ferroelectric thin film on a dielectric layer on a conducting substrate, and arranging the graphene layer over the ferroelectric thin film.

31. The method of claim 27 wherein the providing step comprises depositing the graphene layer on a ferroelectric substrate, and doping the graphene layer with donor or acceptor molecules.

32. The method of claim 27 further comprising forming a top electrode on the ferroelectric thin film.

33. The method of claim 32 further comprising forming a bottom electrode between the ferroelectric thin film and the dielectric layer.

34. The method of claim 26 wherein the providing step comprises chemically deriving the graphene layer from graphene oxide.

35. The method of claim 26 wherein the providing step comprises chemically modifying graphane to provide the graphene layer.

36. The method of claim 26 wherein the providing step comprises growing the graphene layer by chemical vapor deposition (CVD), low pressure CVD, or plasma-enhanced CVD on copper, nickel, cobalt or any other surface, which allows for large-scale graphene.

37. The method of claim 26 wherein the providing step comprises providing the graphene layer as one layer, two layers, three layers or any other gate tunable thickness.

38. The method of claim 26 wherein the providing step comprises providing the graphene layer as a pristine two-dimensional sheet, or patterning into nanoscale dimensions of dots, dot arrays, nanowires or nanowire arrays.

39. The method of claim 26 wherein the providing step comprises providing the layers on a flexible and transparent substrate.

40. The method of claim 27 wherein the providing step comprises providing the graphene layer directly in contact with the ferroelectric layer, or separating the graphene layer from the ferroelectric layer by an ultrathin insulating layer.

41. The method of claim 26 further comprising forming an alternating stack of graphene layer and ferroelectric layer.
